(19) United States
(12) Patent Application Publication
(10) Pub. No.: US 2019/0178945 A1
(43) Pub. Date: Jun. 13, 2019

(54) BATTERY STATE OF CHARGE PREDICTION METHOD AND SYSTEM

(71) Applicant: Beijing Chuangyu Technology Co., Ltd., Beijing (CN)

(72) Inventors: Yanhan Zhuo, Beijing (CN); Ang Zhao, Beijing (CN); Haiming Wu, Beijing (CN); Songli Liu, Beijing (CN)

(21) Appl. No.: 16/110,066

(22) Filed: Aug. 23, 2018

(30) Foreign Application Priority Data
Dec. 13, 2017 (CN) 201711329195.4

(51) Int. Cl. G01R 31/36

(52) U.S. Cl. CPC G01R 31/3651

(57) ABSTRACT

The embodiments of the present disclosure provide a battery state of charge prediction method and system. The method includes obtaining voltages and currents of a battery during charge and discharge; obtaining optimized model parameters with genetic algorithm by optimizing model parameters in a second-order RC equivalent circuit model of the battery according to the voltages and currents of the battery during charge and discharge; obtaining a cubic spline fitting function of state of charge of the battery, building a state of charge prediction model of the battery with extended Kalman filter algorithm according to the optimized model parameters and the cubic spline fitting function; predicting the state of charge of the battery according to the state of charge prediction model. The battery state of charge prediction method and system provided by the embodiments of the present disclosure can improve the prediction accuracy of the state of charge of battery.

### CLAIM OF PRIORITY

This application claims priority to Chinese Patent Application No. 201711329195.4, filed Dec. 13, 2017, the entire contents of which are fully incorporated herein by reference.

### TECHNICAL FIELD

The embodiments of the present disclosure relate to the technical field of battery management, and particularly to a battery state of charge prediction method and system.

### BACKGROUND

Lithium-ion battery as energy storage power source has been widely used in the fields of communication, power system, transportation, etc. As an energy supply component, the working state of the battery is directly related to the safety and operational reliability of the entire system. In order to ensure a good performance and prolong the service life of the battery pack, it is necessary to know the operating state of the battery timely and accurately and to manage and control the battery reasonably and effectively.

An accurate estimation of the state of charge (SOC) of battery is one of the core technologies in the battery energy management system. The SOC of battery cannot be directly measured, and can only be estimated by measuring other physical quantities and using certain mathematical models and algorithms.

Currently used battery SOC estimation methods include open circuit voltage method and ampere-hour integration method. However, the open circuit voltage method requires that the battery must stand for a sufficient period of time to reach a stable state, and it is only suitable for the SOC estimation of the system in a stopped or standby mode, which cannot meet the requirements of online and real-time detection; the ampere-hour integration method is susceptible to the measurement accuracy of current, the accuracy is not high.

Therefore, it is desired to provide a battery state of charge prediction method that satisfies the online and real-time detection requirements and has a high accuracy.

### SUMMARY

The embodiments of the present disclosure provide a battery state of charge prediction method and system.

In one respect, the embodiments of the present disclosure provide a battery state of charge prediction method, including:
obtaining voltages and currents of a battery during charge and discharge;
obtaining optimized model parameters with genetic algorithm by optimizing model parameters in a second-order RC equivalent circuit model of the battery according to the voltages and currents of the battery during charge and discharge;
obtaining a cubic spline fitting function of state of charge of the battery, building a state of charge prediction model of the battery with extended Kalman filter algorithm according to the optimized model parameters and the cubic spline fitting function;
predicting the state of charge of the battery according to the state of charge prediction model.

In another respect, the embodiments of the present disclosure provide a battery state of charge prediction system, including:
at least one processor; at least one memory; an obtaining module, a parameters optimizing module, a model building module and a predicting module stored in the memory, when being executed by the processor,
the obtaining module is configured to obtain voltages and currents of a battery during charge and discharge;
the parameters optimizing module is configured to obtain optimized model parameters with genetic algorithm by optimizing model parameters in a second-order RC equivalent circuit model of the battery according to the voltages and currents of the battery during charge and discharge;
the model building module is configured to obtain a cubic spline fitting function of state of charge of the battery, build a state of charge prediction model of the battery with extended Kalman filter algorithm according to the optimized model parameters and the cubic spline fitting function;
the predicting module is configured to predict the state of charge of the battery according to the state of charge prediction model.

In another respect, the embodiments of the present disclosure provide an electronic device including a processor and a memory; wherein the processor and the memory communicate with each other through a bus; the memory stores program instructions executed by the processor, the processor calls the program instructions to execute the battery state of charge prediction methods above.

In another respect, the embodiments of the present disclosure provide a computer readable storage medium in which computer programs are stored, the battery state of charge prediction methods above are implemented when a processor executes the computer programs.

The battery state of charge prediction method and system provided by the embodiments of the present disclosure can improve the prediction accuracy of the state of charge of battery by obtaining the voltages and currents of the battery during charge and discharge; obtaining the optimized model parameters with the genetic algorithm by optimizing the model parameters in the second-order RC equivalent circuit model of the battery according to the voltages and currents of the battery during charge and discharge; obtaining the cubic spline fitting function of state of charge of the battery, building the state of charge prediction model of the battery with extended Kalman filter algorithm according to the optimized model parameters and the cubic spline fitting function; predicting the state of charge of the battery according to the state of charge prediction model.

### BRIEF DESCRIPTION OF THE DRAWINGS

In order to more clearly describe the embodiments of the present disclosure or the technical solutions in the prior art, the drawings to be used in describing the embodiments or the prior art will be briefly described below, obviously, the drawings in the following description are some embodiments of the present disclosure, for those of ordinary skill in the art, other drawings may also be obtained based on these drawings without any creative work.

FIG. 1 is a flow chart of the battery state of charge prediction method provided by an embodiment of the present disclosure;

FIG. 2 is a structural diagram of the battery state of charge prediction system provided by an embodiment of the present disclosure;

FIG. 3 is a structural diagram of the electronic device provided by an embodiment of the present disclosure;

FIG. 4 is a structural diagram of the battery information on-line monitoring system in the prior art.

### DETAILED DESCRIPTION

In order to make the objectives, technical solutions, and advantages of the embodiments of the present disclosure clearer, the technical solutions of the embodiments of the present disclosure will be described clearly with reference to the accompanying drawings hereinafter. Obviously, the described embodiments are merely some but not all of the embodiments of the present disclosure. On the basis of the embodiments of the present disclosure, all other embodiments obtained by the person of ordinary skill in the art without creative work shall fall within the protection scope of the present disclosure.

FIG. 1 is a flow chart of the battery state of charge prediction method provided by an embodiment of the present disclosure, as shown in FIG. 1, the method includes:
step 10, obtaining voltages and currents of a battery during charge and discharge;
step 11, obtaining optimized model parameters with genetic algorithm by optimizing model parameters in a second-order RC equivalent circuit model of the battery according to the voltages and currents of the battery during charge and discharge;
step 12, obtaining a cubic spline fitting function of state of charge of the battery, building a state of charge prediction model of the battery with extended Kalman filter algorithm according to the optimized model parameters and the cubic spline fitting function;
step 13, predicting the state of charge of the battery according to the state of charge prediction model.

FIG. 4 is a structural diagram of the battery information on-line monitoring system in the prior art. The server can obtain the voltages and currents of the battery to be tested during cyclic charge and discharge. The voltages and currents of the battery during cyclic charge and discharge can be collected through the existing battery information on-line monitoring system.

As shown in FIG. 4, the battery information on-line monitoring system may include a microprocessor 41, a power supply module 42, a battery information processing module 43, a CAN communication module 44, a data storage module 45 and a battery information sensor 46. The microprocessor 41 is connected to the power supply module 42, the battery information processing module 43, the CAN communication module 44 and the data storage module 45 respectively. The battery information processing module 43 is connected to the battery information sensor 46. The battery information sensor 46 can be integrated with voltage sensor, current sensor and temperature sensor. The battery information sensor 46 is directly connected to the battery to be tested. In the embodiments of the present disclosure, the microprocessor 41 may be a MC9S12XET256.

The voltages and currents data of the battery to be tested during charge and discharge obtained by the server may include the voltages and currents obtained by performing charge and discharge test on the battery at regular time intervals. For example, the battery is subjected to the charge and discharge test every 5 hours.

The server may then obtain the optimized model parameters with the existing genetic algorithm by identifying the model parameters in the second-order RC equivalent circuit model according to the voltages and currents of the battery during charge and discharge, wherein the process of identifying the model parameters is the process of optimizing the model parameters.

The server may also obtain the cubic spline fitting function of state of charge of the battery, build the state of charge prediction model of the battery according to the optimized model parameters and the cubic spline fitting function of state of charge; the server may predict the state of charge of the battery according to the state of charge prediction model.

The battery state of charge prediction method provided by the embodiments of the present disclosure can improve the prediction accuracy of the state of charge of battery by obtaining the voltages and currents of the battery during charge and discharge; obtaining the optimized model parameters with the genetic algorithm by optimizing the model parameters in the second-order RC equivalent circuit model of the battery according to the voltages and currents of the battery during charge and discharge; obtaining the cubic spline fitting function of state of charge of the battery, building the state of charge prediction model of the battery with extended Kalman filter algorithm according to the optimized model parameters and the cubic spline fitting function; predicting the state of charge of the battery according to the state of charge prediction model.

Alternatively, on the basis of the embodiments above, the model parameters include: the ohmic internal resistance, electrochemical polarization internal resistance, electrochemical polarization capacitance, concentration internal resistance and concentration polarization capacitance of the battery.

Specifically, the model parameters of the embodiments above may include the ohmic internal resistance, electrochemical polarization internal resistance, electrochemical polarization capacitance, concentration internal resistance and concentration polarization capacitance of the battery to be tested.

The ohmic internal resistance may be denoted to RΩ, the electrochemical polarization internal resistance may be denoted to RS, the electrochemical polarization capacitance may be denoted to CS, the concentration internal resistance may be denoted to R1 and concentration polarization capacitance may be denoted to C1.

The server may obtain the optimized ohmic internal resistance, electrochemical polarization internal resistance, electrochemical polarization capacitance, concentration internal resistance and concentration polarization capacitance on the basis of the existing genetic algorithms, by identifying the above-mentioned model parameters in the second-order RC equivalent circuit model according to the obtained voltages and currents of the battery to be tested during charge and discharge.

The battery state of charge prediction method provided by the embodiments of the present disclosure is more scientific by optimizing the ohmic internal resistance, electrochemical polarization internal resistance, electrochemical polarization capacitance, concentration internal resistance and concentration polarization capacitance in the second-order RC equivalent circuit model with the genetic algorithm.

Alternatively, on the basis of the embodiments above, obtaining the cubic spline fitting function of state of charge of the battery includes:
obtaining state of charges and open circuit voltages of the battery during charge and discharge;
building the cubic spline fitting function of state of charge of the battery according to the state of charges and open circuit voltages of the battery during charge and discharge.

Specifically, the server may obtain the state of charges and open circuit voltages of the battery to be tested during charge and discharge. The state of charges and open circuit voltages may include a state of charge and an open circuit voltage when the battery is in a standing state, a state of charge and open circuit voltage during charge and discharge when a load is applied to the battery, and a state of charge and an open circuit voltage when the battery restores to the standing state after the load is removed.

The server may then build the cubic spline fitting function of state of charge of the battery according to the obtained state of charges and open circuit voltages of the battery.

The battery state of charge prediction method provided by the embodiments of the present disclosure is more scientific by obtaining the state of charges and open circuit voltages of the battery during charge and discharge and then building the cubic spline fitting function of state of charge of the battery according to the state of charges and open circuit voltages of the battery during charge and discharge.

Alternatively, on the basis of the embodiments above, building the state of charge prediction model of the battery with the extended Kalman filter algorithm according to the optimized model parameters and the cubic spline fitting function includes:
building a state equation of the battery according to the optimized model parameters;
building a measurement equation of the battery according to balanced electromotive force, ohmic voltage drop, and RC circuit voltage of the battery;
building the state of charge prediction model of the battery with the extended Kalman filter algorithm according to the measurement equation, the state equation, and the cubic spline fitting function.

Specifically, the server may build the state equation of the battery to be tested according to the optimized model parameters after identifying the model parameters in the second-order RC equivalent circuit model and obtaining the optimized model parameters; the state equation may be represented as:

$${x}_{k} = {i}_{k - 1} [ \begin{matrix}{R}_{Ω} \\ \frac{{R}_{s}}{1 + {R}_{s} {C}_{s}} \\ \frac{{R}_{l}}{1 + {R}_{l} {C}_{l}} \\ \frac{1}{{C}_{cap}}\end{matrix} ] + [ \begin{matrix}0 & 0 & 0 & 0 \\ 0 & \frac{{R}_{s} {C}_{s}}{1 + {R}_{s} {C}_{s}} & 0 & 0 \\ 0 & 0 & \frac{{R}_{l} {C}_{l}}{1 + {R}_{l} {C}_{l}} & 0 \\ 0 & 0 & 0 & 1\end{matrix} ] {x}_{k - 1} + {w}_{k - 1} ;$$

$$let$$

$$A = [ \begin{matrix}0 & 0 & 0 & 0 \\ 0 & \frac{{R}_{s} {C}_{s}}{1 + {R}_{s} {C}_{s}} & 0 & 0 \\ 0 & 0 & \frac{{R}_{l} {C}_{l}}{1 + {R}_{l} {C}_{l}} & 0 \\ 0 & 0 & 0 & 1\end{matrix} ] , B = [ \begin{matrix}{R}_{Ω} \\ \frac{{R}_{s}}{1 + {R}_{s} {C}_{s}} \\ \frac{{R}_{l}}{1 + {R}_{l} {C}_{l}} \\ \frac{1}{{C}_{cap}}\end{matrix} ] ,$$

the state equation may be denoted as: xₖ=Axₖ₋₁+Biₖ₋₁+wₖ₋₁,
wherein

$${x}_{k} = [ \begin{matrix}{u}_{k}^{Ω} \\ {u}_{k}^{s} \\ {u}_{k}^{l} \\ {SOC}_{k}\end{matrix} ] ;$$

wherein, Xₖ indicates the state of charge vector of the battery to be tested at kth time; Xₖ₋₁ indicates the state of charge vector of the battery to be tested at k−1th time; iₖ₋₁ indicates the current corresponding to the state of charge vector of the battery to be tested at k−1th time; wₖ₋₁ indicates the process excitation noise of the battery to be tested at k−1th time, which is related to the measurement noise of the current and can be ignored; C_{cap} indicates the capacity of the battery to be tested; uₖ^{Ω} indicates the ohmic voltage drop at kth time; uₖ^{s} indicates the RC circuit voltage of the battery to be tested before applying the load at kth time; uₖ^{l} indicates the RC circuit voltage of the battery to be tested after applying the load at kth time; SOCₖ indicates the state of charge of the battery to be tested at kth time.

The server may build the measurement equation of the battery according to the balanced electromotive force, ohmic voltage drop, and RC circuit voltage of the battery to be tested, wherein the measurement equation may be denoted as:

uₖ=uₖ^{EMF}−uₖ^{Ω}−uₖ^{s}−uₖ^{l}+wₖ;

wherein Uₖ indicates the voltage of the battery to be tested at kth time; uₖ^{EMF} indicates the balanced electromotive force of the battery to be tested at kth time, the balanced electromotive force and the state of charge of the battery are in a non-linear relation; Wₖ indicates the measurement noise of the battery to be tested at kth time.

The server may then build the state of charge prediction model of the battery with the existing extended Kalman filter algorithms according to the measurement equation, the state equation, and the cubic spline fitting function of state of charge of the battery to be tested, and predict the state of charge of the battery to be tested at a certain time according to the prediction model.

The battery state of charge prediction method provided by the embodiments of the present disclosure is more scientific by building the state equation of the battery to be tested according to the optimized model parameters; building the measurement equation of the battery to be tested according to the balanced electromotive force, ohmic voltage drop, and RC circuit voltage of the battery; building the state of charge prediction model of the battery to be tested with the extended Kalman filter algorithm according to the measurement equation, the state equation, and the cubic spline fitting function of the state of charge of the battery to be tested.

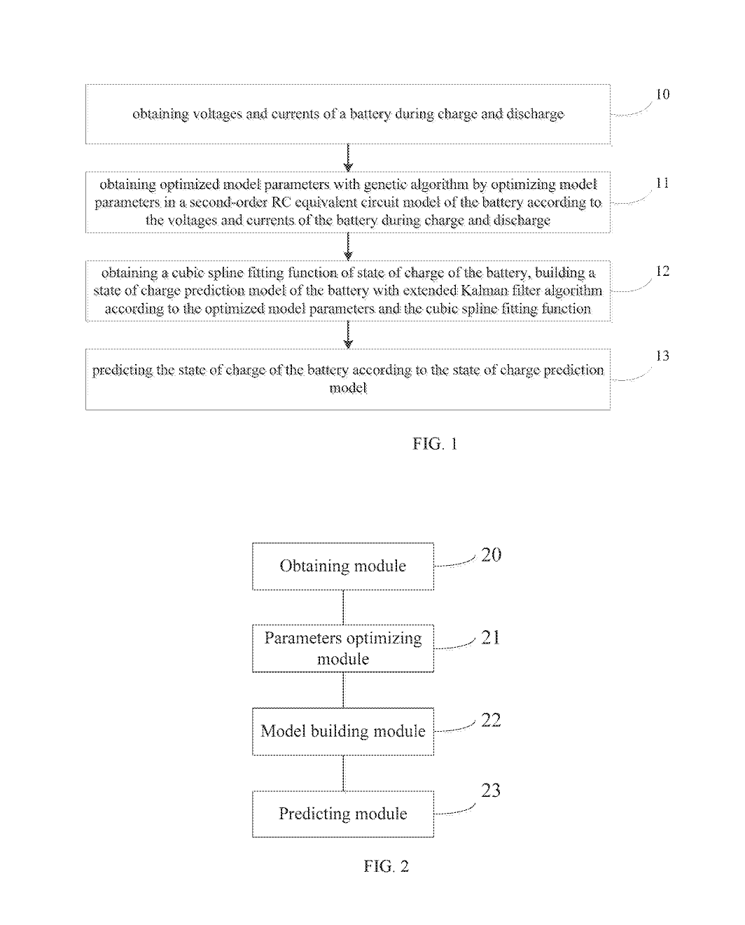

FIG. 2 is a structural diagram of the battery state of charge prediction system provided by an embodiment of the present disclosure. As shown in FIG. 2, the system includes an obtaining module 20, a parameters optimizing module 21, a model building module 22 and a predicting module 23.

It should be noted that the battery state of charge prediction system also includes at least one processor and at least one memory (not shown in the drawings); the modules above are stored in the memory, and when being executed by the processor, the obtaining module 20 is configured to obtain voltages and currents of a battery during charge and discharge; the parameters optimizing module 21 is configured to obtain optimized model parameters with genetic algorithm by optimizing model parameters in a second-order RC equivalent circuit model of the battery according to the voltages and currents of the battery during charge and discharge; the model building module 22 is configured to obtain a cubic spline fitting function of state of charge of the battery, build a state of charge prediction model of the battery with extended Kalman filter algorithm according to the optimized model parameters and the cubic spline fitting function; and the predicting module 23 is configured to predict the state of charge of the battery according to the state of charge prediction model.

The battery state of charge prediction system provided by the embodiments of the present disclosure may include the obtaining module 20, the parameters optimizing module 21, the model building module 22 and the predicting module 23.

The obtaining module 20 can obtain the voltages and currents of the battery to be tested during cyclic charge and discharge; the voltages and currents of the battery to be tested during cyclic charge and discharge can be collected through the existing battery information on-line monitoring system.

As shown in FIG. 4, the battery information on-line monitoring system may include a microprocessor 41, a power supply module 42, a battery information processing module 43, a CAN communication module 44, a data storage module 45 and a battery information sensor 46. Wherein the microprocessor 41 is connected to the power supply module 42, the battery information processing module 43, the CAN communication module 44 and the data storage module 45 respectively; the battery information processing module 43 is connected to the battery information sensor 46; the battery information sensor 46 can be integrated with voltage sensor, current sensor and temperature sensor; the battery information sensor 46 is directly connected to the battery to be tested. In the embodiments of the present disclosure, the microprocessor 41 may be a MC9S12XET256.

The voltages and currents data of the battery to be tested during charge and discharge obtained by the obtaining module 20 may include the voltages and currents obtained by performing charge and discharge test on the battery at regular time intervals. For example, the battery is subjected to the charge and discharge test every 5 hours.

The parameters optimizing module 21 may obtain the optimized model parameters with the existing genetic algorithms by identifying the model parameters in the second-order RC equivalent circuit model of the battery to be tested according to the voltages and currents of the battery during charge and discharge.

The model building module 22 may obtain the cubic spline fitting function of state of charge of the battery, then build the state of charge prediction model of the battery according to the optimized model parameters and the cubic spline fitting function of state of charge; the the model building module 22 may predict the state of charge of the battery according to the state of charge prediction model.

The functions of the battery state of charge prediction system provided by the embodiments of the present disclosure may specifically refer to the method embodiments above, which will not be repeated herein.

The battery state of charge prediction system provided by the embodiments of the present disclosure can improve the prediction accuracy of the state of charge of battery by obtaining the voltages and currents of the battery during charge and discharge; obtaining the optimized model parameters with the genetic algorithm by optimizing the model parameters in the second-order RC equivalent circuit model of the battery according to the voltages and currents of the battery during charge and discharge; obtaining the cubic spline fitting function of state of charge of the battery, building the state of charge prediction model of the battery with extended Kalman filter algorithm according to the optimized model parameters and the cubic spline fitting function; predicting the state of charge of the battery according to the state of charge prediction model.

Alternatively, on the basis of the embodiments above, the parameters optimizing module is specifically configured to: optimize ohmic internal resistance, electrochemical polarization internal resistance, electrochemical polarization capacitance, concentration internal resistance and concentration polarization capacitance of the battery with the genetic algorithm.

Specifically, the parameters optimizing module in the embodiments above may obtain the optimized model parameters with the existing genetic algorithms by identifying the model parameters in the second-order RC equivalent circuit model according to the voltages and currents of the battery to be tested during charge and discharge obtained by the obtaining module. The model parameters may include the ohmic internal resistance, electrochemical polarization internal resistance, electrochemical polarization capacitance, concentration internal resistance and concentration polarization capacitance of the battery to be tested.

The battery state of charge prediction system provided by the embodiments of the present disclosure is more scientific by optimizing the ohmic internal resistance, electrochemical polarization internal resistance, electrochemical polarization capacitance, concentration internal resistance and concentration polarization capacitance in the second-order RC equivalent circuit model with the genetic algorithm.

Alternatively, on the basis of the embodiments above, the model building module includes an obtaining sub module and a function fitting sub module; wherein the obtaining sub module is configured to obtain state of charges and open circuit voltages of the battery during charge and discharge; the function fitting sub module is configured to build the cubic spline fitting function of state of charge of the battery according to the state of charges and open circuit voltages of the battery during charge and discharge.

Specifically, the model building module of the embodiments above may include the obtaining sub module and the function fitting sub module.

The obtaining sub module may obtain the state of charges and open circuit voltages of the battery to be tested during charge and discharge, wherein the state of charges and open circuit voltages may include a state of charge and an open circuit voltage when the battery is in a standing state, state of charges and open circuit voltages during charge and discharge when a load is applied to the battery, and a state of charge and an open circuit voltage when the battery restores to the standing state after the load is removed.

The function fitting sub module may then build the cubic spline fitting function of state of charge of the battery according to the obtained state of charges and open circuit voltages of the battery.

The battery state of charge prediction system provided by the embodiments of the present disclosure is more scientific by obtaining the state of charges and open circuit voltages of the battery during charge and discharge and then building the cubic spline fitting function of state of charge of the battery according to the state of charges and open circuit voltages of the battery during charge and discharge.

Alternatively, on the basis of the embodiments above, the model building module includes a state equation sub module, a measurement equation sub module and a model building sub module; wherein the state equation sub module is configured to build the state equation of the battery according to the optimized model parameters; the measurement equation sub module is configured to build the measurement equation of the battery according to the balanced electromotive force, ohmic voltage drop, and RC circuit voltage of the battery; and the model building sub module is configured to build the state of charge prediction model of the battery with the extended Kalman filter algorithm according to the measurement equation, the state equation, and the cubic spline fitting function.

Specifically, the model building module of the embodiments above may include the state equation sub module, the measurement equation sub module and the model building sub module.

The state equation sub module may build the state equation of the battery to be tested according to the optimized model parameters obtained by the parameters optimizing module; the state equation may be represented as:

$${x}_{k} = {i}_{k - 1} [ \begin{matrix}{R}_{Ω} \\ \frac{{R}_{s}}{1 + {R}_{s} {C}_{s}} \\ \frac{{R}_{l}}{1 + {R}_{l} {C}_{l}} \\ \frac{1}{{C}_{cap}}\end{matrix} ] + [ \begin{matrix}0 & 0 & 0 & 0 \\ 0 & \frac{{R}_{s} {C}_{s}}{1 + {R}_{s} {C}_{s}} & 0 & 0 \\ 0 & 0 & \frac{{R}_{l} {C}_{l}}{1 + {R}_{l} {C}_{l}} & 0 \\ 0 & 0 & 0 & 1\end{matrix} ] {x}_{k - 1} + {w}_{k - 1} ;$$

$$let$$

$$A = [ \begin{matrix}0 & 0 & 0 & 0 \\ 0 & \frac{{R}_{s} {C}_{s}}{1 + {R}_{s} {C}_{s}} & 0 & 0 \\ 0 & 0 & \frac{{R}_{l} {C}_{l}}{1 + {R}_{l} {C}_{l}} & 0 \\ 0 & 0 & 0 & 1\end{matrix} ] , B = [ \begin{matrix}{R}_{Ω} \\ \frac{{R}_{s}}{1 + {R}_{s} {C}_{s}} \\ \frac{{R}_{l}}{1 + {R}_{l} {C}_{l}} \\ \frac{1}{{C}_{cap}}\end{matrix} ] ,$$

the state equation may be denoted as: xₖ=Axₖ₋₁+Biₖ₋₁+wₖ₋₁,

wherein

$${x}_{k} = [ \begin{matrix}{u}_{k}^{Ω} \\ {u}_{k}^{s} \\ {u}_{k}^{l} \\ {SOC}_{k}\end{matrix} ] ;$$

wherein, Xₖ indicates the state of charge vector of the battery to be tested at kth time; Xₖ₋₁ indicates the state of charge vector of the battery to be tested at k−1th time; iₖ₋₁ indicates the current corresponding to the state of charge vector of the battery to be tested at k−1th time; wₖ₋₁ indicates the process excitation noise of the battery to be tested at k−1th time, which is related to the measurement noise of the current and can be ignored; C_{cap} indicates the capacity of the battery to be tested; uₖ^{Ω} indicates the ohmic voltage drop at kth time; uₖ^{s} indicates the RC circuit voltage of the battery to be tested before applying the load at kth time; uₖ^{l} indicates the RC circuit voltage of the battery to be tested after applying the load at kth time; SOCₖ indicates the state of charge of the battery to be tested at kth time.

The server may build the measurement equation of the battery according to the balanced electromotive force, ohmic voltage drop, and RC circuit voltage of the battery to be tested, wherein the measurement equation may be denoted as:

uₖ=uₖ^{EMF}−uₖ^{Ω}−uₖ^{s}−uₖ^{l}+wₖ;

wherein Uₖ indicates the voltage of the battery to be tested at kth time; uₖ^{EMF} indicates the balanced electromotive force of the battery to be tested at kth time, the balanced electromotive force and the state of charge of the battery are in a non-linear relation; Wₖ indicates the measurement noise of the battery to be tested at kth time.

The model building sub module may then build the state of charge prediction model of the battery with the existing extended Kalman filter algorithms according to the measurement equation, the state equation, and the cubic spline fitting function of state of charge of the battery to be tested, and predict the state of charge of the battery to be tested at a certain time according to the prediction model.

The battery state of charge prediction system provided by the embodiments of the present disclosure is more scientific by building the state equation of the battery to be tested according to the optimized model parameters; building the measurement equation of the battery to be tested according to the balanced electromotive force, ohmic voltage drop, and RC circuit voltage of the battery; building the state of charge prediction model of the battery to be tested with the extended Kalman filter algorithm according to the measurement equation, the state equation, and the cubic spline fitting function of the state of charge of the battery to be tested.

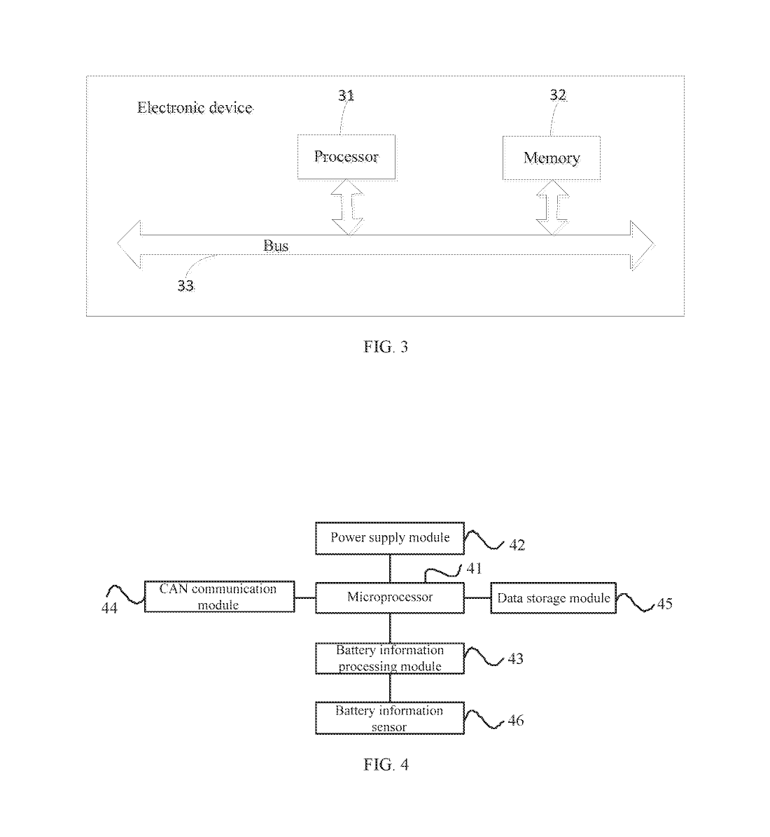

FIG. 3 is a structural diagram of the electronic device provided by an embodiment of the present disclosure. As shown in FIG. 3, the electronic device may include a processor 31, a memory 32 and a bus 33.

The processor 31 and the memory 32 communicate with each other through the bus 33; the processor 31 is configured to call program instructions in the memory 32 to perform the methods provided by each method embodiment above, including, for example, obtaining voltages and currents of a battery during charge and discharge; obtaining optimized model parameters with genetic algorithm by optimizing model parameters in a second-order RC equivalent circuit model of the battery according to the voltages and currents of the battery during charge and discharge; obtaining a cubic spline fitting function of state of charge of the battery, building a state of charge prediction model of the battery with extended Kalman filter algorithm according to the optimized model parameters and the cubic spline fitting function; predicting the state of charge of the battery according to the state of charge prediction model.

The embodiment of the present disclosure provides a computer program product including computer programs stored in a non-transitory computer readable storage medium, the computer program including program instructions, when executed by a computer, the computer is able to execute the methods provided by each method embodiment above, including, for example, obtaining voltages and currents of a battery during charge and discharge; obtaining optimized model parameters with genetic algorithm by optimizing model parameters in a second-order RC equivalent circuit model of the battery according to the voltages and currents of the battery during charge and discharge; obtaining a cubic spline fitting function of state of charge of the battery, building a state of charge prediction model of the battery with extended Kalman filter algorithm according to the optimized model parameters and the cubic spline fitting function; predicting the state of charge of the battery according to the state of charge prediction model.

The embodiment of the present disclosure provides a non-transitory computer readable storage medium, which stores computer instructions instructing a computer to execute the methods provided by each method embodiment above, including, for example, obtaining voltages and currents of a battery during charge and discharge; obtaining optimized model parameters with genetic algorithm by optimizing model parameters in a second-order RC equivalent circuit model of the battery according to the voltages and currents of the battery during charge and discharge; obtaining a cubic spline fitting function of state of charge of the battery, building a state of charge prediction model of the battery with extended Kalman filter algorithm according to the optimized model parameters and the cubic spline fitting function; predicting the state of charge of the battery according to the state of charge prediction model.

The embodiments such as the electronic device described above are only illustrative, in which the units described as separate parts may or may not be physically separated, and the parts displayed as units may or may not be physical units, that is, they may be located in one place, or may also be distributed to multiple network units. According to actual needs, some or all of the modules may be selected to achieve the objects of the solutions of the embodiments. Those of ordinary skill in the art can understand and implement without creative work.

Through the description of the embodiments above, those skilled in the art can clearly understand that each embodiment can be implemented by means of software with necessary universal hardware platform, and can also, of course, by means of hardware. Based on such understanding, the technical solutions of the present disclosure, or the part thereof contributing to the prior art, or parts thereof can be embodied in the form of a software product stored in a storage medium, such as ROM/RAM, magnetic disk, optical disk, etc., the software product includes certain instructions so that a computer device (may be a personal computer, a server, or a network device, etc.) performs the methods described in each of the embodiments, or some parts of the embodiments.

Finally, it should be noted that each embodiment above is only used to illustrate rather than to limit the technical solutions of the embodiments of the present disclosure; although the present disclosure has been described in detail with reference to the foregoing embodiments, those of ordinary skill in the art should understand that they can still modify the technical solutions described in the foregoing embodiments, or equivalently replace some or all of the technical features therein; and these modifications or replacements do not separate the essence of the corresponding technical solutions from the spirit and scope of the technical solutions of each of the embodiments of the present disclosure.

1. A battery state of charge prediction method, comprising:
obtaining voltages and currents of a battery during charge and discharge;
obtaining optimized model parameters with genetic algorithm by optimizing model parameters in a second-order RC equivalent circuit model of the battery according to the voltages and currents of the battery during charge and discharge;
obtaining a cubic spline fitting function of state of charge of the battery, building a state of charge prediction model of the battery with extended Kalman filter algorithm according to the optimized model parameters and the cubic spline fitting function; and
predicting the state of charge of the battery according to the state of charge prediction model.

2. The method of claim 1, wherein the model parameters comprise ohmic internal resistance, electrochemical polarization internal resistance, electrochemical polarization capacitance, concentration polarization internal resistance and concentration polarization capacitance of the battery.

3. The method of claim 1, wherein obtaining the cubic spline fitting function of state of charge of the battery comprises:
obtaining state of charges and open circuit voltages of the battery during charge and discharge; and
building the cubic spline fitting function of state of charge of the battery according to the state of charges and open circuit voltages of the battery during charge and discharge.

4. The method of claim 1, wherein building the state of charge prediction model of the battery with the extended Kalman filter algorithm according to the optimized model parameters and the cubic spline fitting function comprises:
building a state equation of the battery according to the optimized model parameters;
building a measurement equation of the battery according to balanced electromotive force, ohmic voltage drop, and RC circuit voltage of the battery; and
building the state of charge prediction model of the battery with the extended Kalman filter algorithm according to the measurement equation, the state equation, and the cubic spline fitting function.

5. A battery state of charge prediction system, comprising:
at least one processor; at least one memory; an obtaining module, a parameters optimizing module, a model building module and a predicting module stored in the memory, when being executed by the processor,
the obtaining module is configured to obtain voltages and currents of a battery during charge and discharge;
the parameters optimizing module is configured to obtain optimized model parameters with genetic algorithm by optimizing model parameters in a second-order RC equivalent circuit model of the battery according to the voltages and currents of the battery during charge and discharge;
the model building module is configured to obtain a cubic spline fitting function of state of charge of the battery, build a state of charge prediction model of the battery with extended Kalman filter algorithm according to the optimized model parameters and the cubic spline fitting function; and
the predicting module is configured to predict the state of charge of the battery according to the state of charge prediction model.

6. The system of claim 5, wherein the parameters optimizing module is specifically configured to optimize ohmic internal resistance, electrochemical polarization internal resistance, electrochemical polarization capacitance, concentration polarization internal resistance and concentration polarization capacitance of the battery with the genetic algorithm.

7. The system of claim 5, wherein the model building module comprises:
an obtaining sub module configured to obtain state of charges and open circuit voltages of the battery during charge and discharge; and
a function fitting sub module configured to build the cubic spline fitting function of state of charge of the battery according to the state of charges and open circuit voltages of the battery during charge and discharge.

8. The system of claim 5, wherein the model building module comprises:
a state equation sub module configured to build a state equation of the battery according to the optimized model parameters;
a measurement equation sub module configured to build a measurement equation of the battery according to balanced electromotive force, ohmic voltage drop, and RC circuit voltage of the battery; and
a model building sub module configured to build the state of charge prediction model of the battery with the extended Kalman filter algorithm according to the measurement equation, the state equation, and the cubic spline fitting function.

9. A computer readable storage medium, in which computer programs are stored, wherein the method of claim 1 is implemented when a processor executes the computer programs.
